(19) United States
(12) Patent Application Publication
(10) Pub. No.: US 2007/0298592 A1
(43) Pub. Date: Dec. 27, 2007

(54) Method for manufacturing single crystalline gallium nitride material substrate

(75) Inventors: Jen-Inn Chyi, Jhongli City (TW); Guan-Ting Chen, Jhongli City (TW)

Correspondence Address: TROXELL LAW OFFICE PLLC, 5205 LEESBURG PIKE, SUITE 1404, FALLS CHURCH, VA, 22041, US

(73) Assignee: National Central University, Taoyuan (TW)

(21) Appl. No.: 11/514,332

(22) Filed: Sep. 1, 2006

(30) Foreign Application Priority Data
Jun. 22, 2006 (TW) 095122438

(51) Int. Cl. H01L 21/20

(52) U.S. Cl. 438/479

(57) ABSTRACT

A gallium nitride substrate is originally grown above a silicon substrate. The present invention easily separates the gallium nitride substrate from the silicon substrate. And the separation is done with a simple etching so that the cost is low.

### FIELD OF THE INVENTION

The present invention relates to a manufacturing method; more particularly, relates to obtaining a gallium nitride (GaN) substrate easily separated from a silicon (Si) substrate.

### DESCRIPTION OF THE RELATED ARTS

GaN materials have been attracted for short wavelength light-emitting diodes (LED), laser diodes, high-power electronic devices, etc. The technique for growing the GaN material is applied on sapphire substrate or silicon carbide (SiC) substrate nowadays. However, the sapphire substrate is not conductive and has a poor heat dissipation so that the efficiency of GaN based devices is hard to be improved greatly. And, regarding the SiC substrate, it is too expensive to meet financial benefits. Hence, a new trend is to grow GaN material on a Si substrate, a gallium arsenide (GaAs), etc.; and this technique is a main technique to obtain a large-size GaN material or GaN substrate.

However, the crystal types, the lattice arrangements, the lattice lengths and the thermal expansion coefficients between GaN and Si are different, although cost can be greatly reduced by growing the GaN material on a Si substrate. Therefore, when growing GaN, many lattice defects happen to the GaN material obtained and its critical thickness is thin. But, in order to be used as a GaN substrate, the GaN material must have few lattice defects to grow thicker. Consequently, a few prior arts are used to reduce lattice defects with selective growing methods for GaN material to grow on Si substrates.

As shown in FIG. 3A to FIG. 3C, a first prior art is proclaimed by S. Tanaka, etc., where GaN is grown on a Si substrate. A silicon oxide (SiO₂) layer 32 is deposited on a Si substrate 31 at first. Then, a periodic ridge structure of SiO₂ mask 33 is obtained from the SiO₂ layer 32 by an etching of a lithography with exposing a surface of silicon crystals outside. Then a GaN bulk layer 34 is grown on the surface of silicon crystals. Because GaN can not be grown on a SiO₂ surface, GaN is grown on two lateral surfaces of SiO₂ masks 33 to obtain GaN crystals with few lattice defects. Yet, a shortcoming still exists. That is, because lattices of GaN and Si do not match, the GaN material puts much stress on the Si substrate so that it is hard to grow a thick GaN layer to fabricate a GaN substrate with a big size.

As shown in FIG. 4A and FIG. 4B, a second prior art is proclaimed by T. M. Katona, etc. A Si substrate is etched into a Si ridge structure to obtain a stripe patterned silicon substrate 41 at first. Then a GaN bulk layer 42 is grown on an upper surface of the stripe patterned silicon substrate 41 together with being grown on the lateral surfaces. One of its drawbacks include that GaN crystals can even be grown at the bottom of the Si ridge structure providing few selections for crystal growth. The same shortcoming for the first prior art is also included in the drawbacks of the second prior art. The GaN material puts much stress on the Si substrate too so that a break in the GaN crystal may occurs when fabricating a GaN bulk layer of a big size.

The above two prior arts both fabricate GaN substrates, but not GaN substrates of big sizes. Hence, the prior arts do not fulfill users' requests on actual use.

### SUMMARY OF THE INVENTION

The main purpose of the present invention is to separate a GaN substrate from a Si substrate with a saved cost through etching a dielectric layer.

To achieve the above purpose, the present invention is a method for manufacturing single crystalline GaN material substrate, comprising steps of: (a) obtaining a Si substrate; (b) overlaying a dielectric layer on the Si substrate; (c) overlaying a Si crystal layer on the dielectric layer; (d) overlaying a mask layer on the Si crystal layer; (e) processing a lithography to the mask layer to form a patterned mask layer; (f) etching the Si crystal layer until stopping at the dielectric layer to form a Si crystal island; (g) removing the patterned mask layer; (h) growing a GaN material on the Si crystal island to form a structure of a GaN substrate; and (i) applying an etching solution to the structure of the GaN substrate to separate the GaN substrate from the Si substrate to etching the dielectric layer, where the dielectric layer is made with SiO₂ or silicon nitride (SiN); the mask layer is made of a polymer, SiO₂ or SiN; the etching in step (f) is a wet etching or a dry etching; the GaN material in step (h) is GaN, aluminum gallium nitride (AlGaN), indium gallium nitride (InGaN) or aluminum gallium indium nitride (AlGaInN); and the etching solution is made with SiO₂, hydrofluoric acid (HF) or phosphoric acid (H₃PO₄). Accordingly, a novel method for manufacturing single crystalline GaN material substrate is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the view showing the flow chart of the preferred embodiment according to the present invention;

FIG. 2A to FIG. 2I are the views showing the structures in step (a) to step (i);

FIG. 3A to FIG. 3C are the views showing the structures of the first prior art; and

FIG. 4A and FIG. 4B are the views showing the structures of the second prior art.

### DESCRIPTION OF THE PREFERRED EMBODIMENT

The following description of the preferred embodiment is provided to understand the features and the structures of the present invention.

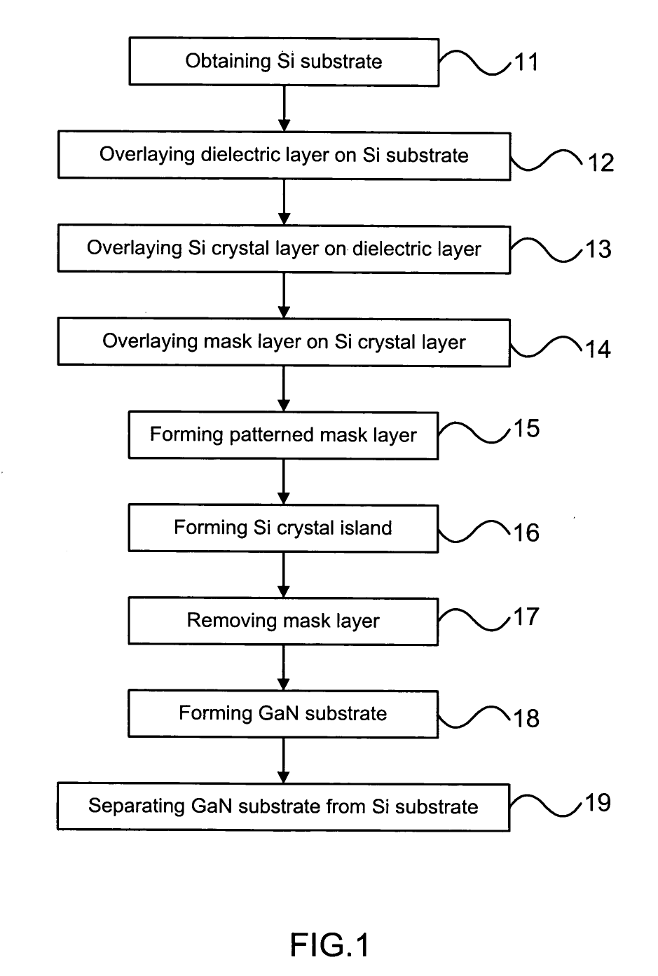

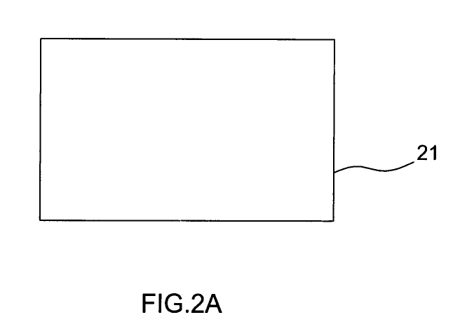

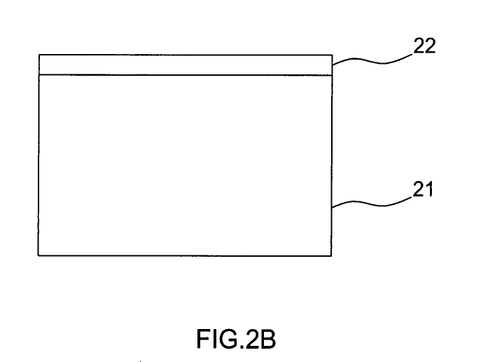

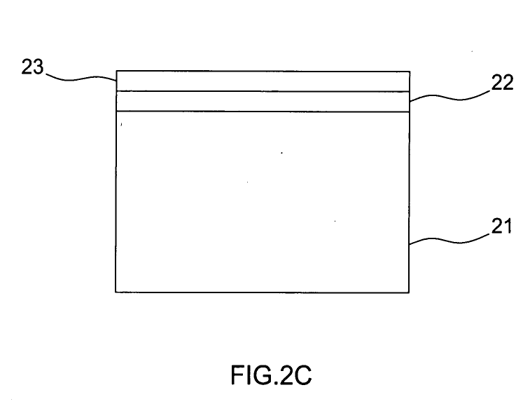

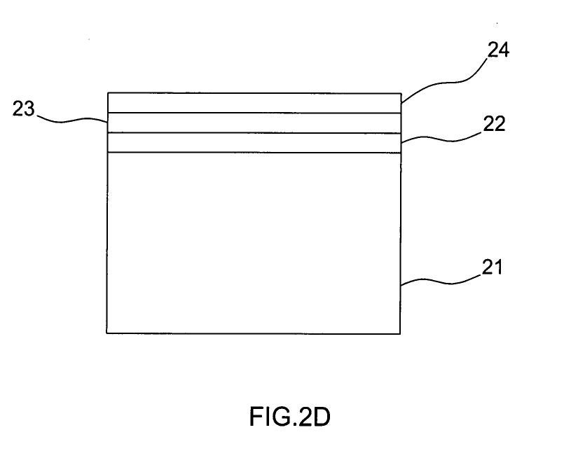

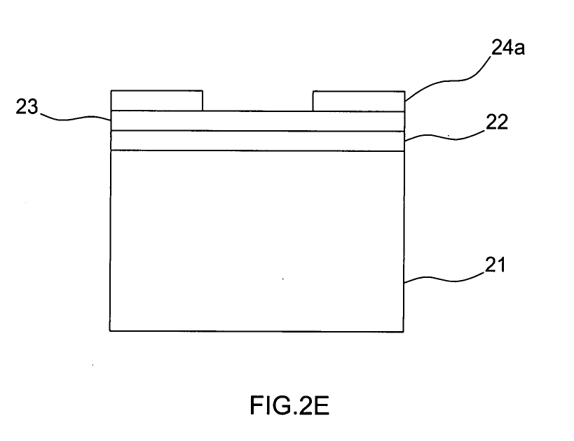

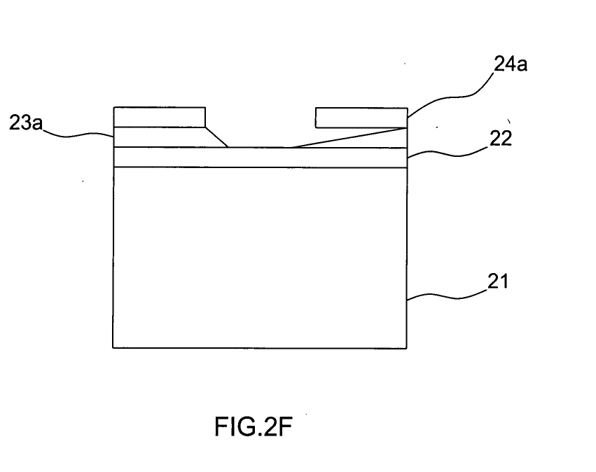

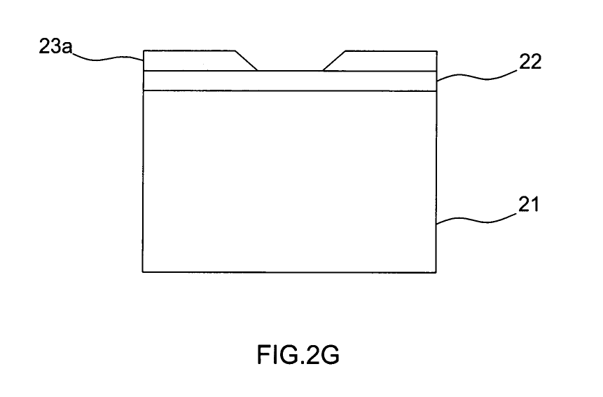

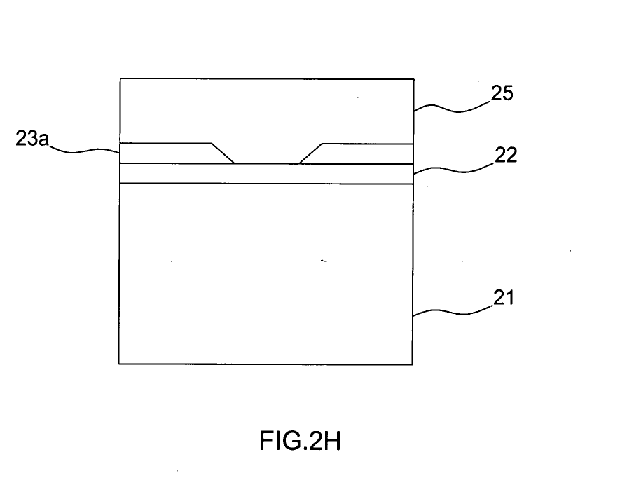

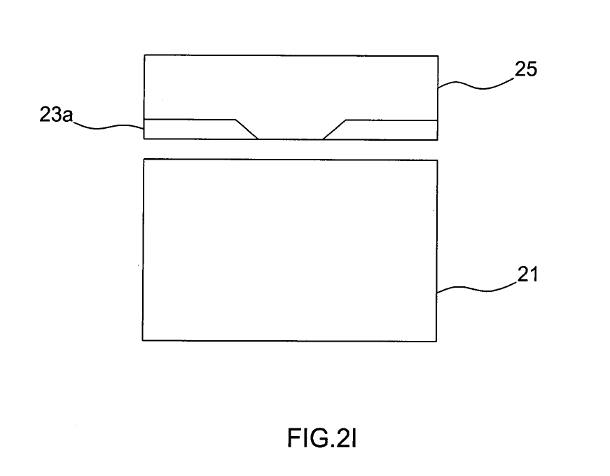

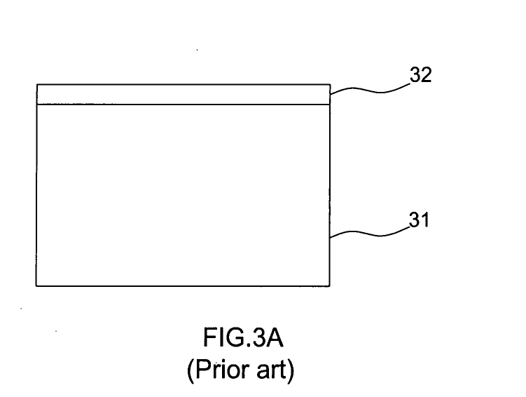

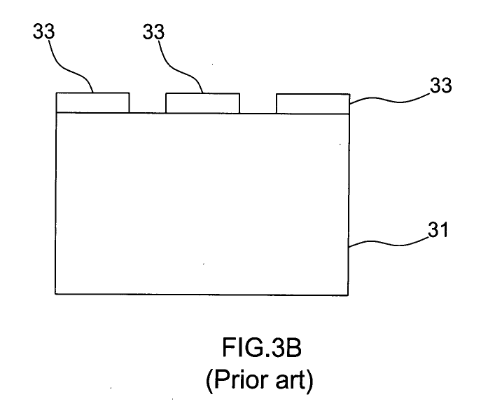

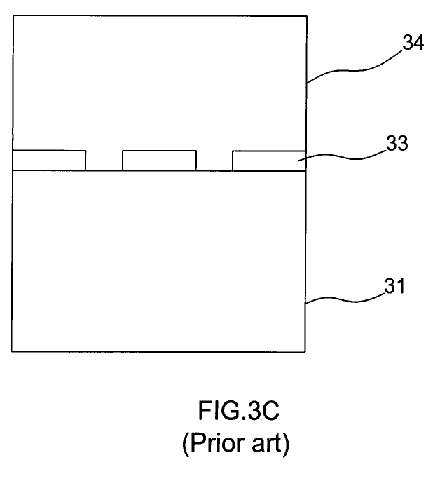

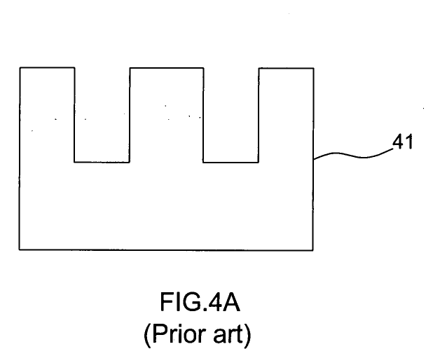

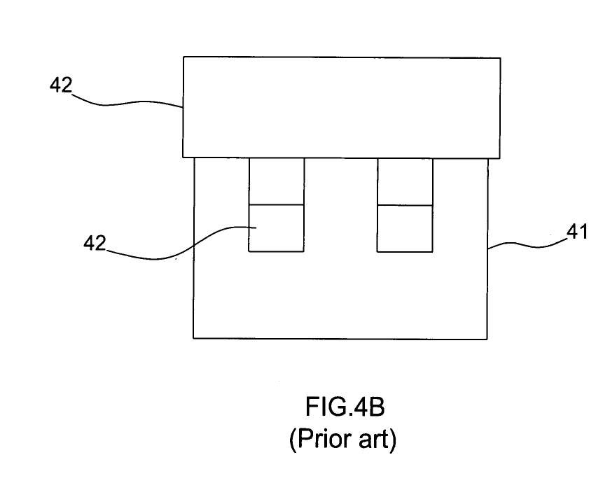

Please refer to FIG. 1 and FIG. 2A to FIG. 2I, which are a view showing a flow chart and views showing structures in step (a) to step (i) of a preferred embodiment according to the present invention. As shown in the figures, the present invention is a method for manufacturing single crystalline gallium nitride (GaN) material substrate, comprising the following steps:

(a) Obtaining a Si substrate 11: A silicon (Si) substrate 21 is obtained.

(b) Overlaying a dielectric layer on the Si substrate 12: A dielectric layer 22 is overlaid on the Si substrate 21, where the dielectric layer 22 is made of silicon oxide (SiO₂) or silicon nitride (SiN). At first, an ion-implantation of oxygen atoms having high energy is implanted into the Si substrate 21 at a default depth; then a rapid temperature annealing is processed to combine the oxygen atoms and original silicon atoms of the Si substrate 21 to obtain the dielectric layer 22.

(c) Overlaying a Si crystal layer on the dielectric layer 13: A Si crystal layer 23 is overlaid on the dielectric layer 22.

(d) Overlaying a mask layer on the Si crystal layer 14: A mask layer 24 is overlaid on the Si crystal layer 23, where the mask layer 24 is made of a polymer, SiO₂ or SiN.

(e) Forming a patterned mask layer 15: The mask layer 24 is processed with a lithography to form a patterned mask layer 24a, where the lithography is a photolithography, an electron-beam lithography or a focus-ion-beam lithography.

(f) Forming a Si crystal island 16: The Si crystal layer 23 is processed with an etching to form a Si crystal island 23a; and the etching is stopped at the dielectric layer 22, where the etching is a dry etching or a wet etching.

(g) Removing the mask layer 17: The patterned mask layer 24a is removed.

(h) Forming a GaN substrate 18: A GaN material is grown on the Si crystal island 23a to form a structure of a GaN substrate 24, where the GaN material is GaN, aluminum gallium nitride (AlGaN), indium gallium nitride (InGaN) or aluminum gallium indium nitride (AlGaInN); and the GaN material is grown on the Si crystal island 23a through a molecular beam epitaxy, a metalorganic vapor phase epitaxy or a hydride vapor phase epitaxy.

(i) Separating the GaN substrate from the Si substrate 19: An etching solution is applied to the structure of the GaN substrate 25 to etch the dielectric layer 22 so that the GaN substrate 25 is separated from the Si substrate 21. Therein, the etching solution is made with SiO₂ etching solution, hydrofluoric acid (HF) or phosphoric acid (H₃PO₄).

To sum up, the present invention is a method for manufacturing single crystalline gallium nitride material substrate, where a separation procedure is greatly simplified with a saved cost through a simple etching.

The preferred embodiment herein disclosed is not intended to unnecessarily limit the scope of the invention. Therefore, simple modifications or variation is belonging to the equivalent of the scope of the claims and the instructions disclosed herein for a patent are all within the scope of the present invention.

What is claimed is:

1. A method for manufacturing single crystalline gallium nitride (GaN) material substrate comprising steps of:
(a) obtaining a silicon (Si) substrate;
(b) deposing a dielectric layer on said Si substrate;
(c) deposing a Si crystal layer on said dielectric layer;
(d) deposing a mask layer on said Si crystal layer;
(e) processing a lithography to said mask layer to obtain a patterned mask layer;
(f) processing an etching to said Si crystal layer until stopping at said dielectric layer to obtain a Si crystal island;
(g) removing said patterned mask layer;
(h) growing a GaN material on said Si crystal island to obtain a structure of a GaN substrate; and
(i) using an etching solution to said structure of said GaN substrate to separate said GaN substrate from said Si substrate by etching said dielectric layer.

2. The method according to claim 1, wherein said dielectric layer in step (b) is obtained by an ion-implantation of oxygen atoms into said Si substrate to combine said oxygen atoms with silicon atoms in said Si substrate through a rapid temperature annealing.

3. The method according to claim 1, wherein said mask layer is made of a material selected from a group consisting of a polymer, silicon oxide (SiO₂) and silicon nitride (SiN).

4. The method according to claim 1, wherein said lithography in step (e is selected from a group consisting of a photolithography, an electron-beam lithography and a focus-ion-beam lithography.

5. The method according to claim 1, wherein said etching in step (f) is selected from a group consisting of a wet etching and a dry etching.

6. The method according to claim 1, wherein said dielectric layer is made with a material selected from a group consisting of silicon oxide (SiO₂) or SiN.

7. The method according to claim 1, wherein said GaN material in step (h) is selected from a group consisting of GaN, aluminum gallium nitride (AlGaN), indium gallium nitride (InGaN) and aluminum gallium indium nitride (AlGaInN).

8. The method according to claim 1, wherein said GaN material in step (h) is grown on said Si crystal island through an epitaxy selected from a group consisting of a molecular beam epitaxy, a metal organic vapor phase epitaxy and a hydride vapor phase epitaxy.

9. The method according to claim 1 wherein said etching solution in step (i) is made with a material selected from a group consisting of SiO₂ etching solution, hydrofluoric acid (HF) and phosphoric acid (H₃PO₄).
